(19) United States
(12) Patent Application Publication
(10) Pub. No.: US 2014/0377964 A1
(43) Pub. Date: Dec. 25, 2014

(54) APPARATUS FOR OXIDATION AND ANNEALING PROCESSES AND METHOD FOR THE SAME

(71) Applicants: Seon Heo, Seoul (KR); Chang Hyun Son, Seoul (KR)

(72) Inventors: Seon Heo, Seoul (KR); Chang Hyun Son, Seoul (KR)

(73) Assignee: LG INNOTEK CO., LTD., Seoul (KR)

(21) Appl. No.: 14/241,947

(22) PCT Filed: Aug. 10, 2012
(86) PCT No.: PCT/KR2012/006414

§ 371 Date: Jun. 13, 2014

(30) Foreign Application Priority Data
Aug. 30, 2011 (KR) 10-2011-0087108

(51) Int. Cl. H01L 21/687; H01L 21/324; C23C 16/56; H01L 21/677; C23C 16/448; H01L 21/02; H01L 21/67

(52) U.S. Cl. CPC H01L 21/68764; H01L 21/02233; H01L 21/324; H01L 21/67098; H01L 21/67712; C23C 16/448; C23C 16/56
USPC 438/770; 118/724; 118/719

(57) ABSTRACT

The disclosure relates to an apparatus for oxidation and annealing processes comprising: a chamber; an oxidizing unit located in the chamber, where an oxidizing process for a subject to be processed is conducted; and an annealing unit located in the chamber, where an annealing process for the subject to be processed is conducted.

Further, The disclosure relates to a method for the oxidation and annealing processes comprising: preparing a chamber comprising an oxidizing unit and an annealing unit; preparing a subject to be processed on a susceptor located in the oxidizing unit; oxidizing the subject to be processed; converting atmosphere of the oxidizing unit; transferring the subject to be processed to the annealing unit; and annealing the subject to be processed.

### TECHNICAL FIELD

The disclosure relates to an apparatus for oxidation and annealing processes and a method for the same.

### BACKGROUND ART

A silicon carbide single crystal used as a semiconductor device material may be prepared by a single crystal growth process. Particularly, PVT (Physical Vapor Transport) method using sublimation, i.e., seeded growth sublimation has been mainly used to prepare the single crystal industrially. The silicon carbide powder as a source material is put in a melting pot, and the silicon carbide crystal as the seed is arranged at the top of the pot. Then, temperature gradient is formed between the source material and the seed, so as to diffuse the source material in the melting pot to the seed. As a result, it is recrystallized and single crystal ingot is grown.

For this single crystal growth, a seed holder for fixing the seed and a focusing tube for collecting the sublimated silicon carbide gas to the seed may be further provided thereto.

After completing the single crystal growth, an oxidation process may be conducted to separate the grown single crystal from the seed holder and the focusing tube. Further, an annealing process at high temperature is conducted to relieve or remove the stress in the single crystal. Because the oxidation process is conducted under oxygen atmosphere, a SiC heater or a kanthal heater and the like, which is not to be damaged under oxygen atmosphere, are used during the oxidation process. However, the temperature of these heaters for the oxidation process is difficult to be increased to the temperature for conducting the annealing process, 2200° C. or more. Thus, the annealing process uses resistance heating method or induction heating method using a graphite heater under argon gas or nitrogen gas atmosphere.

Because the oxidation and the annealing processes can't use the same heater and have to be conducted under different conditions, two processes have to be conducted in different chambers. Thus, there is a problem that the oxidation and the annealing processes can't be conducted serially. Further, when the temperature increasing or cooling process is conducted quickly while the oxidation and the annealing processes are being performed, defects in an ingot may be easily generated due to heat shock or stress. Therefore, there is a problem that process time would be increased long because the oxidation and the annealing processes have to be conducted slowly.

### DISCLOSURE OF INVENTION

### Technical Problem

The embodiment provides an apparatus for oxidation and annealing processes and a method for the same, which can improve process efficiency and reduce process time.

### Solution to Problem

The apparatus for oxidation and annealing processes according to one embodiment including: a chamber; an oxidizing unit located in the chamber, where an oxidizing process for a subject to be processed is conducted; and an annealing unit located in the chamber, where an annealing process for the subject to be processed is conducted.

The method for oxidation and annealing processes according to another embodiment comprises: preparing a chamber provided with the oxidizing unit and the annealing unit; preparing a subject to be processed on a susceptor located in the oxidizing unit; oxidizing the subject to be processed; converting atmosphere of the oxidizing unit; transferring the subject to be processed to the annealing unit; and annealing the subject to be processed.

### Advantageous Effects of Invention

According to the apparatus for oxidation and annealing processes according to embodiments, an oxidizing unit where the oxidation is conducted, and an annealing unit where the annealing process is conducted are located in the same chamber. Thus, the oxidation and the annealing processes can be conducted serially. Therefore, for the annealing process after the oxidation, time for moving the object to be processed from the chamber for the oxidation process to the chamber for the annealing process may be saved. That is, time needed for a cooling process and a temperature increasing process for the annealing processes after the oxidation process may be saved. Because the cooling process and the temperature increasing process can be omitted, the possibility of generation of defects in the subject to be processed may be reduced. Particularly, if the subject to be processed is a silicon single crystal, a high-quality wafer may be provided by reducing the possibility of generation of defects in the crystal.

The method for the oxidation and the annealing processes according to the embodiments may provide a process method having the effects previously described.

### BRIEF DESCRIPTION OF DRAWINGS

FIG. 1 is an exploded-perspective view showing an apparatus for oxidation and annealing processes according to one embodiment.

FIG. 2 is a sectional view showing a cross section cut along A-A′ of FIG. 1.

FIGS. 3 to 5 are sectional views for describing a method for oxidation and annealing processes.

### MODE FOR THE INVENTION

In the description of the embodiments, it will be understood that, when a layer (film), a region, a pattern or a structure is referred to as being “on” or “under” a substrate, another layer (film), another region, a pad or another pattern, it can be “directly” or “indirectly” on the other layer, or one or more intervening layers may also be present. Such a position of the layer has been described with reference to the drawings.

The thickness and size of each layer (film), region, pattern or structure shown in the drawings may be exaggerated, omitted or schematically drawn for the purpose of convenience or clarity. In addition, the size of elements does not utterly reflect an actual size.

Hereinafter, exemplary embodiments will be described in detail with reference to accompanying drawings.

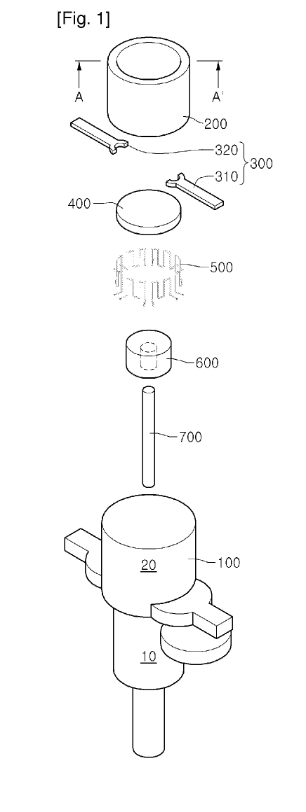

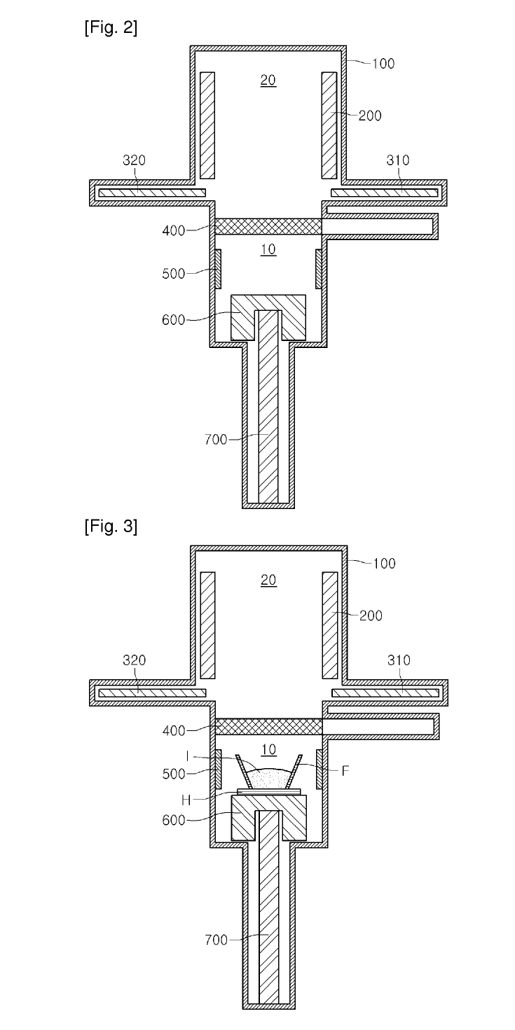

Referring to FIGS. 1 and 2, the apparatus for oxidation and annealing processes according to one embodiment will be described in detail.

FIG. 1 is an exploded oblique view showing an apparatus for oxidation and annealing processes according to one embodiment. FIG. 2 is a sectional view showing a cross section cut along A-A′ of FIG. 1.

Referring to FIGS. 1 and 2, the apparatus for oxidation and annealing processes according to one embodiment includes: a chamber 100; an oxidizing unit 10 and an annealing unit 20 which are disposed inside the chamber 100; a first heating unit 200 (500? [symbol] ); a second heating unit 500 (200? [symbol] ); a gate 400; a susceptor 600; a transfer unit 700; and a susceptor supporting unit 300.

The chamber 100 may be cylindrical shape. The chamber 100 may be a cylindrical tube shape such that the susceptor 600 and the transfer unit 700 received in the chamber 100 can be moved. Further, the chamber 100 may includes a space where the susceptor supporting unit 300 and the gate 400 received in the chamber 100 may move. That is, the sides of the susceptor supporting unit 300 and the gate 400 may protrude such that the susceptor supporting unit 300 and the gate 400 move rightward and leftward. The chamber 100 may contain quartz.

The chamber 100 may include the oxidizing unit 10 and the annealing unit 20.

In the oxidizing unit 10, a subject to be processed may be oxidized. The first heating unit 200 may be located in the oxidizing unit 10 for oxidation process. The first heating unit 200 may be a kanthal heater. However, the embodiment is not limited thereto, and the first heating unit 200 may be a SiC heater. When the oxidation process is conducted in the oxidizing unit 10, the kanthal heater may heat the oxidizing unit 10 to maintain it at high temperature. Further, when the oxidation process is conducted in the oxidizing unit 10, the oxidizing unit 10 may be kept under oxygen atmosphere.

Then, in the annealing unit 20, the subject to be processed may be annealed. The second heating unit 500 may be located in the annealing unit 20 for the annealing process. The second heating unit 500 may be a graphite heater. When the annealing process is conducted in the annealing unit 20, the graphite heater may heat the annealing unit 20 to maintain it at the temperature for annealing. Further, when the annealing process is conducted in the annealing unit 20, the annealing unit 20 may be kept under argon atmosphere.

The oxidizing unit 10 and the annealing unit 20 may be arranged vertically in the chamber 100. As shown in FIG. 2, the annealing unit 20 may be located over the oxidizing unit 10.

Because the oxidizing unit 10 and the annealing unit 20 are located in the same chamber 100, the oxidation and annealing processes may be serially conducted. Thus, for the annealing process after the oxidation process, time for moving the object to be processed from the chamber 100 for the oxidation process to the chamber 100 for the annealing process may be saved. That is, time needed for a cooling process and a temperature increasing process for the annealing processes after the oxidation process may be saved. Because the cooling process and the temperature increasing process can be omitted, the possibility of generation of defects in the subject to be processed may be reduced. Particularly, if the subject to be processed is a silicon single crystal, the possibility of generation of defects in the crystal may be reduced, so as to provide a high-quality wafer.

The gate 400 may be located between the oxidizing unit 10 and the annealing unit 20. The gate 400 may separate the oxidizing unit 10 and the annealing unit 20 in the chamber 100. Thus, although the oxidizing unit 10 and the annealing unit 20 are located in the same chamber 100, the oxidation and the annealing processes may be conducted separately by the gate 400.

The gate 400 may move in the chamber 100. Referring to FIG. 1, the gate 400 may be provided to move rightward and leftward in the chamber 100. That is, the gate 400 may move from a body of the chamber 100, where the oxidizing unit 10 and the annealing unit 20 are located, to the sides of the chamber 100.

Specifically, if the gate 400 is located while separating the oxidizing unit 10 and the annealing unit 20, the oxidizing unit 10 and the annealing unit 20 may have an independent space, respectively. Accordingly, the oxidation process or the annealing process may be conducted independently.

Further, if the subject to be processed may be transferred from the oxidizing unit 10 to the annealing unit 20, or from the annealing unit 20 to the oxidizing unit 10, the gate 400 may be opened. That is, a moving path of the subject to be processed between the oxidizing unit 10 and the annealing unit 20 may be formed by moving the gate 400 to the protruded spaces in the side of the chamber 100.

Then, the susceptor 600 may fix the subject to be processed. The subject to be processed may be located on the susceptor 600. The susceptor 600 may move between the oxidizing unit 10 and the annealing unit 20 by the transfer unit 700. Thus, the oxidation process and the annealing processes of the subject to be processed on the susceptor 600 may be conducted.

The transfer unit 700 may transfer the susceptor 600. That is, the transfer unit 700 may transfer the subject to be processed on the susceptor 600. The transfer unit 700 may move between the oxidizing unit 10 and the annealing unit 20. Referring to FIG. 2, the transfer unit 700 may move vertically in the chamber 100. Specifically, it may move from the oxidizing unit 10 to the annealing unit 20. That is, when the subject to be processed has to be transferred for the annealing process after completing the oxidation process, it may be transferred by the transfer unit 700.

The susceptor supporting unit 300 may support the susceptor 600. Referring to FIG. 2, the susceptor supporting unit 300 may be located in the annealing unit 20.

The susceptor supporting unit 300 may move in the chamber 100. Referring to FIG. 2, the susceptor supporting unit 300 may be provided to move rightward to leftward in the chamber 100. That is, the susceptor supporting unit 300 may move from the body of the chamber 100 to the sides of the chamber 100

The susceptor supporting unit 300 may include a first supporting unit 310 and a second supporting unit 320. The first supporting unit 310 and the second supporting unit 320 may be located in the both sides of the chamber 100, respectively. The first supporting unit 310 and the second supporting unit 320 may support both sides of the susceptor 600.

Specifically, when the subject to be processed is annealed in the annealing unit 20, the susceptor supporting unit 300 may support the subject to be processed. The transfer unit 700 may support the susceptor 600 in the oxidizing unit 10, but, for separating and closing the oxidizing unit 10 and the annealing unit 20, it is difficult to support the susceptor 600 with the transfer unit 700 in the annealing unit 20. Thus, the annealing unit 20 may include the separate susceptor supporting unit 300 to support the susceptor 600.

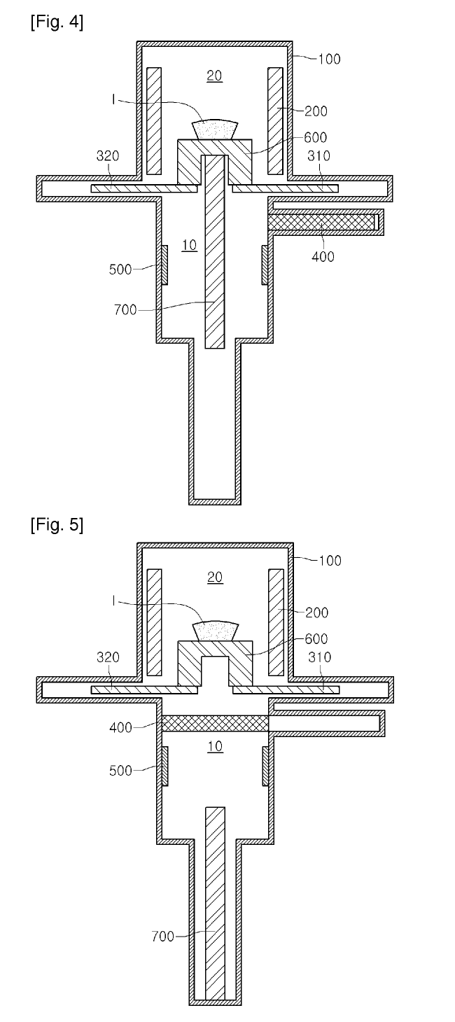

Herein after, referring to FIGS. 3 to 5, the method for the oxidation and the annealing processes according to another embodiment will be described. For clear and brief description, detail description for the contents, which are identical or similar with the previously described contents, will be omitted.

FIGS. 3 to 5 are sectional views for describing a method for oxidation and annealing processes.

The method for the oxidation and the annealing processes according to another embodiment comprises: steps of preparing the chamber; preparing the subject to be processed; oxidizing the object to be processed; converting atmosphere; transferring the object to be processed; annealing the object to be processed.

In the step for preparing the chamber, the chamber 100 including the oxidizing unit 10 and the annealing unit 20 may be prepared.

In the step for preparing the subject to be processed, the subject to be processed may be fixed on the susceptor 600 located in the oxidizing unit 10. Herein, the subject to be processed may be a silicon ingot. Specifically, it may be a silicon ingot I grown in an ingot growing apparatus. Referring to FIG. 2, the silicon ingot I may be attached to a seed holder H fixing the seed for the single crystal growth. Further, a focusing tube F may enclose the silicon ingot I.

Referring to FIG. 3, in the oxidizing step, the subject to be processed may be oxidized in the oxidizing unit 10. At this time, the gate 400 located between the oxidizing unit 10 and the annealing unit 20 may cover the oxidizing unit 10 tightly. The oxidizing unit 10 may be kept under oxygen atmosphere. Specifically, through the oxidizing step, the seed holder H attached to the silicon ingot I, and the focusing tube F may be removed.

Then, in the converting step, a pretreating step to transfer the subject to be processed to the annealing unit 20 may be conducted. Specifically, in the converting step, oxygen atmosphere of the oxidizing unit 10 may be converted to argon atmosphere. The embodiments are not limited thereto, and the oxygen atmosphere may be converted to nitrogen atmosphere. The annealing process in the annealing unit 20 may be conducted under argon atmosphere, and when the subject to be processed is transferred from the oxidizing unit 10 to the annealing unit 20, the oxidizing unit 10 may also be kept under argon atmosphere as the annealing unit 20, so as to prevent shock to the subject to be processed caused by sudden conversion of the atmosphere. Further, the converting step may comprise a step of controlling the temperature of the annealing unit 20 equivalent to the temperature of the oxidizing unit 10. Through this, heat shock to the subject to be processed caused by the temperature difference between the oxidizing unit 10 and the annealing unit 20 may be prevented. Particularly, the pretreatment process is an essential process because the chamber 100 according to the embodiment includes the oxidizing unit 10 and the annealing unit 20 together.

Then, referring to FIG. 4, in the transferring step, the subject to be processed may be transferred to the annealing unit 20. When it is transferred from the oxidizing unit 10 to the annealing unit 20, it may be transferred through the transfer unit 700 located under the susceptor 600. The transfer unit 700 may be provided to allow the oxidizing unit 10 and the annealing unit 20 to be moved, and therefore, it may transfer the subject to be processed. At this time, for transferring the subject to be processed, the gate 400 may be opened. That is, the gate 400 separating the oxidizing unit 10 and the annealing unit 20 may form a moving path of the subject to be processed by moving to the sides of the chamber 100.

After transferring the subject to be processed, the susceptor 600 may be fixed with the susceptor supporting unit 300 located in the annealing unit 20.

Then, referring to FIG. 5, the annealing process may be conducted. At this time, the gate 400 may be closed for separating and closing the oxidizing unit 10 and the annealing unit 20.

In the annealing step, the annealing process may be conducted. Through this, internal stress of the ingot I as the subject to be processed may be relieved or removed.

Through the method for the oxidation and the annealing processes according to the embodiment, process time may be reduced by conducting the oxidation and the annealing processes serially. Further, a high-quality wafer may be provided by reducing the possibility of generation of defects in the subject to be processed.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for oxidation and annealing processes comprising:
a chamber;
an oxidizing unit located in the chamber, where an oxidizing process for an subject to be processed is conducted; and
an annealing unit located in the chamber, where an annealing process for the subject to be processed is conducted.

2. The apparatus for oxidation and annealing processes of claim 1, wherein the oxidizing process and the annealing process are serially conducted.

3. The apparatus for oxidation and annealing processes of claim 1, wherein the oxidizing unit and the annealing unit are vertically arranged in the chamber.

4. The apparatus for oxidation and annealing processes of claim 3, wherein the annealing unit is located over the oxidizing unit.

5. The apparatus for oxidation and annealing processes of claim 1, further comprises a gate, which is located between the oxidizing unit and the annealing unit, and separates the oxidizing unit and the annealing unit.

6. The apparatus for oxidation and annealing processes of claim 5, wherein the gate is provide to form a path of the subject to be processed.

7. The apparatus for oxidation and annealing processes of claim 6, wherein the gate moves rightward and leftward.

8. The apparatus for oxidation and annealing processes of claim 1, wherein the subject to be processed is serially transferred between the oxidizing unit and the annealing unit in the chamber.

9. The apparatus for oxidation and annealing processes of claim 1, further comprises a transfer unit for transferring the subject to be processed.

10. The apparatus for oxidation and annealing processes of claim 9, wherein the transfer unit moves between the oxidizing unit and the annealing unit.

11. The apparatus for oxidation and annealing processes of claim 9, further comprises a susceptor for fixing the subject to be processed.

12. The apparatus for oxidation and annealing processes of claim 1, further comprises a first heating unit located in the oxidizing unit.

13. The apparatus for oxidation and annealing processes of claim 12, wherein the first heating unit is a kanthal heater.

14. The apparatus for oxidation and annealing processes of claim 1, further comprises a second heating unit located in the annealing unit.

15. The apparatus for oxidation and annealing processes of claim 14, wherein the second heating unit is a graphite heater.

16. The apparatus for oxidation and annealing processes of claim 11, further comprises a susceptor supporting unit for supporting the susceptor in the annealing unit.

17. The apparatus for oxidation and annealing processes of claim 16, wherein the susceptor supporting unit comprises a first supporting unit and a second supporting unit, and the first supporting unit and the second supporting unit support both sides of the susceptor supporting unit.

18. A method for oxidation and annealing processes comprising:
preparing a chamber including an oxidizing unit and an annealing unit;
preparing a subject to be processed on a susceptor located in the oxidizing unit;
oxidizing the subject to be processed;
converting atmosphere of the oxidizing unit;
transferring the subject to be processed to the annealing unit; and
annealing the subject to be processed.

19. The method for oxidation and annealing processes of claim 18, wherein, in the converting step, oxygen atmosphere is converted to argon atmosphere.

20. The method for oxidation and annealing processes of claim 18, wherein, in the converting step, the annealing unit temperature is controlled to the equivalent temperature of the oxidizing unit.

21. (canceled)
